(19) United States
(12) Patent Application Publication
(10) Pub. No.: US 2015/0197295 A1
(43) Pub. Date: Jul. 16, 2015

(54) THIN FILM COATING ON UNDERCARRIAGE TRACK PINS

(71) Applicant: CATERPILLAR INC., Peoria, IL (US)

(72) Inventors: Bao FENG, Dunlap (CH); Mark Steven DIEKEVERS, Germantown Hills, IL (US); Steven Charles TAYLOR, Germantown Hills, IL (US); Joseph Ryan SULLIVAN, Bartonville, IL (US); Douglas Trent WEAVER, Metamora, IL (US)

(73) Assignee: CATERPILLAR INC., Peoria, IL (US)

(21) Appl. No.: 14/152,372

(22) Filed: Jan. 10, 2014

(51) Int. Cl. B62D 55/21; C23C 14/06; C23C 14/34; C23C 28/04; C23C 16/27; C23C 16/50

(52) U.S. Cl. CPC B62D 55/21; C23C 16/27; C23C 16/50; C23C 14/34; C23C 28/04; C23C 14/0635

(57) ABSTRACT

An undercarriage track joint assembly includes a first link having a first bore at a first end and a second bore at a second, opposite end, and a second link having a first bore at a first end and a second bore at a second, opposite end. A pin may extend between the first and second links, positioned at least partially within the first bores of the first and second links, or partially within the second bores of the first and second links. A bushing may extend between the first and second links, a central axial bore being defined through the bushing. The pin may extend through the central axial bore through the bushing, the pin being coated with a diamond-like carbon (DLC) coating over at least a portion of an outer diameter surface of the pin, the coating providing a contact layer between the outer diameter surface of the pin and an inner diameter surface of the central axial bore through the bushing.

### TECHNICAL FIELD

The present disclosure relates generally to undercarriage track pins and, more particularly, to undercarriage track pins with a thin film coating.

### BACKGROUND

Many earth-working machines, such as, for example, loaders, tractors, and excavators, include tracked undercarriages to facilitate movement of the machines over ground surfaces. Such undercarriages include drive sprockets that rotate track assemblies about one or more idlers or other guiding components to propel the machines over the ground surfaces. Each track assembly includes a pair of parallel chains, each made up of a series of links, joined to each other by pins and/or bushings (the combination of which is sometimes referred to as a cartridge assembly). Due to wear from abrasion and impacts experienced during use, undercarriage maintenance costs often constitute more than one quarter of the total costs associated with operating the earth-working machines.

A known cartridge assembly for coupling links is disclosed in U.S. Patent Application Publication No. 2012/0267947 by Johannsen et al. The cartridge assembly includes a pin accommodated within an inner bushing, which is, in turn, accommodated within an outer bushing. End portions of the inner bushing are surrounded by inserts, and end portions of the pin are surrounded by collars. The pin is provided with a central, axially oriented lubricant channel, which serves as a reservoir for lubricant and delivers lubricant to a gap between the pin and the inner bushing, and to a gap between the inner bushing and the outer bushing. The lubricant is retained by seals positioned between the outer bushing and inserts, and by seals positioned between the inserts and collars positioned around the axial ends of the pin.

The cartridge assembly may provide certain benefits that are particularly important for some applications. However, it may have certain drawbacks. For example, providing both an inner bushing and an outer bushing may increase the complexity and cost of the cartridge. The disclosed embodiments may help solve these problems.

### SUMMARY

One disclosed embodiment relates to an undercarriage track joint assembly. The track joint assembly may include a first link having a first bore at a first end and a second bore at a second, opposite end. The track joint assembly may also include a second link having a first bore at a first end and a second bore at a second, opposite end. Additionally, the track joint assembly may include a pin extending between the first and second links and positioned at least partially within the first bores of the first and second links, or partially within the second bores of the first and second links. The track joint assembly may also include a bushing extending between the first and second links, a central axial bore being defined through the bushing. In addition, the track joint assembly may include the pin extending through the central axial bore through the bushing. The pin may be coated with a diamond-like carbon (DLC) coating over at least a portion of an outer diameter surface of the pin, the coating providing a contact layer between the outer diameter surface of the pin and an inner diameter surface of the central axial bore through the bushing.

Another disclosed embodiment relates to a track pin for use in an undercarriage track joint assembly. The track pin may include an outer diameter surface prepared by a finishing operation that substantially removes surface asperities left by machining operations. The track pin may also include a coating applied over the outer diameter surface. The coating may include a sputtered underlayer, and an amorphous diamond-like carbon (a-DLC) outer layer.

A further disclosed embodiment relates to a method of manufacturing a pin for use in an undercarriage track joint assembly. The method may include finishing an outer diameter surface of the pin using a finishing process that substantially removes surface asperities left by machining operations. The method may further include depositing an underlayer over the outer diameter surface of the pin by sputtering with a transition metal carbide target, and applying an outer layer of diamond-like carbon (DLC) over the underlayer.

### BRIEF DESCRIPTION OF THE DRAWINGS

FIG. 1 is a perspective view of a track joint assembly according to the present disclosure;

FIG. 2 is a cross-section of the track joint assembly of FIG. 1; and

FIG. 3 is a cross-section of another track joint assembly.

### DETAILED DESCRIPTION

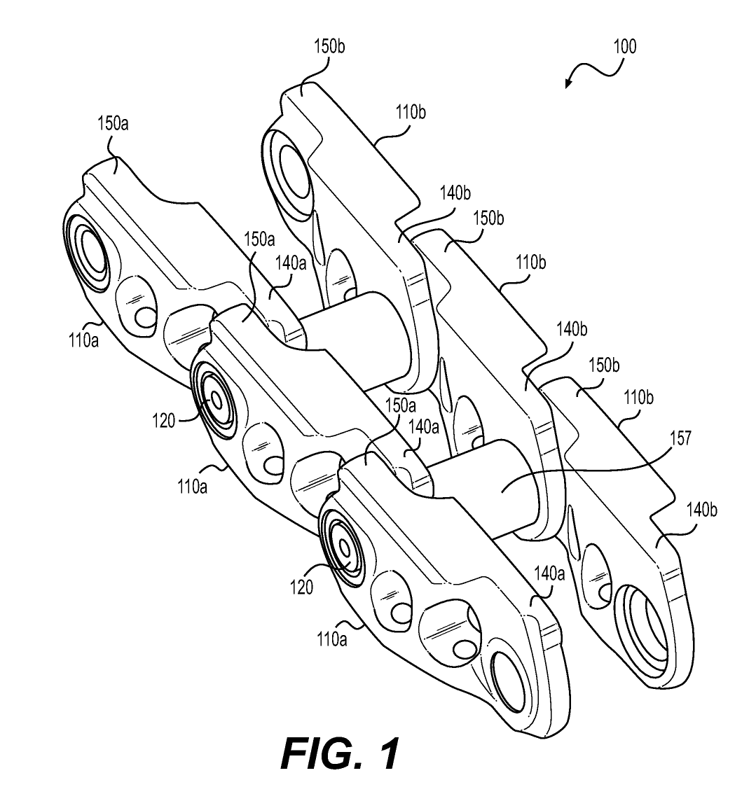

FIG. 1 illustrates an exemplary undercarriage track joint assembly 100 for a track-type machine. For example, the track-type machine may be a loader, a tractor, an excavator, a tank, or another mobile machine having track-type traction devices. When operated, a drive sprocket of the track-type machine (not shown) may rotate undercarriage track joint assembly 100 about one or more idlers or other guiding components (not shown) to facilitate movement of the track-type machine.

Track joint assembly 100 may include a series of links 110a joined to each other and to a series of links 110b by laterally disposed pins 120. As shown, links 110a and 110b may be offset links. That is, they may have inwardly offset ends 140a, 140b and outwardly offset ends 150a, 150b. An inwardly offset end 140a, 140b of each link 110a, 110b may be joined to an outwardly offset end 150a, 150b of each adjacent link 110a, 110b. In addition, an inwardly offset end 140a of each link 110a may be joined to an inwardly offset end 140b of an opposing link 110b, and an outwardly offset end 150a of each link 110a may be joined to an outwardly offset end 150b of an opposing link 110b. It should be understood, however, that links 110a and 110b need not be offset links. Rather, in some embodiments, links 110a and 110b may be inner links and outer links. In such embodiments, both ends of each opposing pair of inner links would be sandwiched between ends of opposing outer links, as is known in the art.

Referring to FIG. 1, each pivotal section of track joint assembly 100 may include two links 110a joined to two links 110b. As shown, inwardly offset ends 140a, 140b of links 110a, 110b may be secured to a joint bushing 157. Joint bushing 157 may be at least partially positioned within first bores through inwardly offset ends 140a, 140b of links 110a, 110b, respectively. Similarly, outwardly offset ends 150a, 150b at the opposite ends of links 110a, 110b may be secured to a pin 120. Pin 120 may be at least partially positioned within second bores through outwardly offset ends 150a, 150b. For example, the securing may be by way of press-fits. The first bores through the inwardly offset ends for accommodating joint bushing 157 may be larger in diameter than the second bores through the outwardly offset ends for accommodating pin 120. Specifically, bushing 157 may be press-fit into the first, larger diameter bores through inwardly offset ends 140a, 140b, and pin 120 may be press-fit into the second, smaller diameter bores through outwardly offset ends 150a, 150b. Bushing 157 may be secured in ways other than press fitting, such as by way of welds, snap rings, or other mechanisms known in the art.

In alternative implementations, a first link may have a first bore at a first end and a second bore of approximately the same diameter as the first bore at a second, opposite end of the first link. A second link may also have a first bore at a first end and a second bore of approximately the same diameter as the first bore at a second, opposite end of the second link. A pin may extend between the first and second links, and may be positioned at least partially within the first bores of the first and second links, or partially within the second bores of the first and second links. A bushing may extend between the first and second links, a central axial bore being defined through the bushing. The bushing may not be press fit into the first or second bores through the links, but rather may be free to rotate relative to the links. In some implementations the bushing may not extend into the first or second bores through the links, with the length of the bushing being approximately the same as the distance between the first and second links. The pin may extend through the central axial bore through the bushing, and may be secured in various ways to the first and second links. The bushing may rotate relative to the pin and relative to the links. This feature may reduce the amount of scuffing and wear on the outer diameter surface of the bushing as the bushing comes into contact with a drive sprocket on a track-type machine.

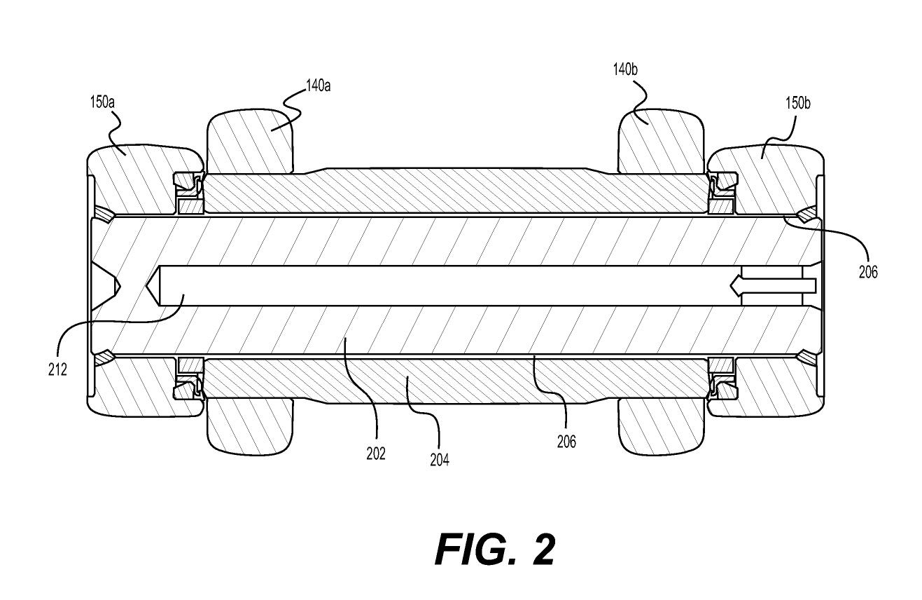

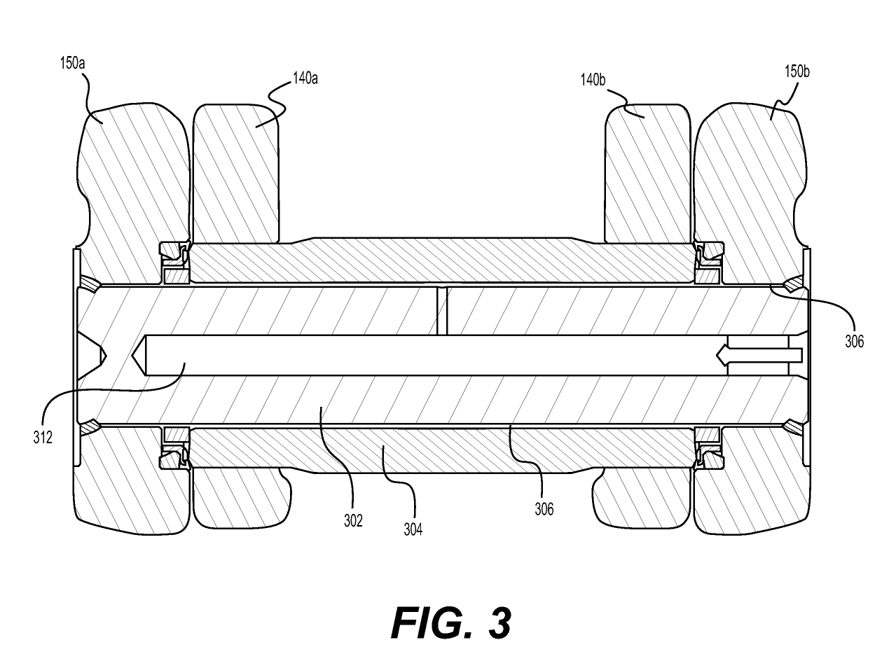

As shown in the implementations of FIGS. 2 and 3, pin 202, 302 may be positioned coaxially inside a central axial bore through joint bushing 204, 304, respectively. Joint bushing 204, 304 may rotate relative to pin 202, 302, allowing inwardly offset ends 140a, 140b to pivot relative to outwardly offset ends 150a, 150b as track joint assembly 100 rotates. In order to facilitate such rotation, the outer diameter surface of pin 202, 302 may be coated with a diamond-like carbon (DLC) coating 206, 306 to reduce friction between joint bushing 204, 304 and pin 202, 302. DLC as used herein refers to carbon based thin films, which may include amorphous diamond-like carbon (a-DLC), or ta-C for tetrahedral amorphous carbon. a-DLC may be further classified as amorphous carbon (a-C), or hydrogenated amorphous carbon (a-C:H). Alternative implementations may include coating an inner diameter surface of the central axial bore through the joint bushing, rather than the outer diameter surface of the pin. In a disclosed implementation, at least the outer diameter surface of the pin may be provided with an isotropic surface finish and a hard thin film that includes the DLC coating over the isotropic surface finish.

Diamond-like carbon (DLC) thin films belong to a material family possessing low friction, high wear resistance, high scuffing resistance, and high galling resistance compared to steel. Galling failure is known to occur during the sliding contact between the pins and bushings in undercarriage track joint assemblies, particularly under high load applications. High load applications, such as incurred on larger, heavy-duty machinery, have typically mitigated the risk of galling through the use of sleeve bearings positioned around the outer diameter surface of the pins between the pins and the bushings. The use of sleeve bearings adds additional cost and design complexity. The hard thin film coating including DLC applied over the outer diameter surface of the pin may eliminate the need for a sleeve bearing between the pin and the bushing in high load applications. such as on large earth-moving tractors and bulldozers.

Track pin 120, 202, 302 may be initially prepared for coating by performing an isotropic finishing process or other finishing process to the outer diameter surface of the pin. The isotropic finishing substantially removes surface asperities while maintaining the integrity of the underlying material of the pin. Surface asperities are the peaks and valleys that cause unevenness or roughness of the surface as a result of machining operations. In an exemplary implementation, the isotropic finishing process may use oxalic acids or other chemicals to gently oxidize the outer diameter surface of the pin. This step helps to render any surface asperities left by earlier machining processes more susceptible to micro-honing. The micro-honing may be performed by tumbling the pin in a chamber with non-abrasive finishing stones such as ceramic beads. The isotropic finishing process is a technique of final machining in a controlled and gentle manner that results in removal of most of the positive or peak surface areas left behind by other machining operations. One of ordinary skill in the art will recognize that other final surface preparation processes may be performed in order to substantially remove surface asperities.

According to various exemplary implementations, the outer diameter surface of the pin may have an arithmetic average surface roughness Ra (hereinafter Ra) of less than about 0.1 μm. The outer diameter surface of the pin may be finished to the desired Ra using any of a number of known machining, or surface finishing, processes. The outer diameter surface may also be subjected to the isotropic surface finishing processes discussed above such that peaks occurring as a result of the machining or finishing processes used to achieve the desired Ra are removed. An isotropic surface finish, as described herein, refers to a particular surface finish in which peaks of the surface asperities have been removed, and does not insinuate a specific process for providing the isotropic surface finish. Such processes may include any known chemical and/or mechanical processes, including vibratory finishing processes, to achieve the desired isotropic surface finish.

The coating 206, 306 shown in FIGS. 2 and 3, respectively, preferably has a nano-hardness of at least about 10 gigapascals (GPa), and even more preferably, at least about 20 GPa. As discussed above, the coating may include an amorphous diamond-like carbon layer (a-DLC), which provides low friction and high wear resistance. The outer diameter surface of the pin may be first provided with an isotropic finish, and then sputtered with an underlayer of a first radial thickness that may include carbon doped with one or more transition metals. The sputtering of an underlayer may assist in the adhesion of an outer layer of a-DLC, as well as providing additional support for the outer layer. The sputtering process may form the underlayer by sputtering with a transition metal carbide target. The transition metal carbide target may include one or more elements from the chromium group (also known as group VIB) on the periodic table, including Chromium (Cr) and Tungsten (W). Even more preferably, the sputtering process may form the underlayer by sequentially sputtering transition metal targets with an inert gas, and sputtering transition metal and transition metal carbide targets with a reactive gas. The sputtering process is a physical vapor deposition process that involves ejecting material from a target that is a source of the desired elements to the receiving surface, which is the outer diameter surface of the pin. After the sputtering process has formed the underlayer, a plasma assisted chemical vapor deposition (PACVD) process may be performed in a vacuum chamber to deposit amorphous hydrogenated carbon (a-C:H) from a gas phase over the underlayer. The deposition of the hydrogenated carbon from a gas phase results in an outer layer of a-DLC. In various implementations, tetrahedral amorphous carbon (ta-C) may be used to achieve an even harder coating with a hardness in a range from approximately 40-80 GPa. The ta-C outer layer may be applied in certain applications without first sputtering an underlayer. The a-DLC outer layer of the coating may also be doped with transition metal carbides or other elements, such as silicon. The carbon content of the a-DLC outer layer is also preferably within a range from approximately 60-80 atomic percent (at %). Preferably, the coating has an elasticity sufficient to withstand a load range of applications experiencing contact pressure of up to 2 GPa.

The outer layer of a-DLC in coating 206, 306 may be deposited to a second radial thickness that is approximately twice the first radial thickness of the sputtered underlayer. The total thickness of the underlayer and the a-DLC outer layer is preferably within a range from approximately 2.0-20 μm. Since the thickness of this coating is negligible, there is no need to change existing clearance designs for the pin and bushing. As a result, existing undercarriage track joint assemblies may be retrofitted to include track pins that include the above-disclosed features.

The isotropic surface finish provided to the outer diameter surface of the pin, as discussed above, may provide better support for the coating than a surface not having an isotropic surface finish. For example, if the hard DLC coating is deposited on a surface having sharp peaks left by machining processes, such as grinding, the stress on the peaks may be high and may induce cracking of the coating. Ultimately, cracking of the coating may lead to the separation and/or breaking off of portions of the coating relative to the outer diameter surface of the pin. Since the isotropic surface finish has the sharp peaks removed, a better support base for the coating may be provided.

In addition, the isotropic surface finish in combination with the hard thin film coating 206, 306 may help to break in the inner diameter surface of the central axial bore through joint bushing 204, 304. In particular, since the hard thin film coating 206, 306 on the outer diameter surface of pin 202, 302 is much harder than the inner diameter surface of the bore through joint bushing 204, 304, the hard thin film coating 206, 306 may function to break in the inner diameter surface of the central axial bore through the joint bushing. If the isotropic surface finish were not provided on the outer diameter surface of the pin, the hard thin film coating could include sharp surface peaks and may grind and wear the inner diameter surface of the bore through the bushing. However, since the outer diameter surface of the pin includes the isotropic surface finish, the hard thin film coating is less abrasive than if the outer diameter surface of the pin did not include the isotropic surface finish. As a result, an efficient and effective reduction of the Ra of the inner diameter surface of the joint bushing may be achieved as well. As an additional enhancement to the process of breaking in the inner diameter surface of the central axial bore through the bushing, lubricating fluid may be added through lubrication channels 212, 312 extending into pin 202, 302.

### INDUSTRIAL APPLICABILITY

The disclosed track joint assemblies may be applicable to track-type machines, such as, for example, loaders, tractors, excavators, and tanks, and may facilitate movement of the machines. The disclosed track joint assemblies may have various advantages over prior art track joint assemblies. For example, the disclosed track joint assemblies may be stronger and more durable than prior art track joint assemblies. In addition, manufacturing the disclosed track joint assemblies may cost less than manufacturing prior art track joint assemblies, and may require less material than manufacturing prior art track joint assemblies.

Track joint assembly 100 may include direct connections between links 110a, 110b that strengthen and improve the durability of track joint assembly 100. Specifically, inwardly offset ends 140a, 140b of links 110a, 110b may be directly connected by being secured to bushing 157. Likewise, outwardly offset ends 150a, 150b of links 110a, 110b may be directly connected by being secured to pin 120. Such direct connections between links 110a, 110b may strengthen and improve the durability of track joint assembly 155 by reducing its susceptibility to vibrations and impacts.

Track joint assembly 100 may be configured to facilitate rotation of bushing 157 relative to pin 120 even when pin 120 is solid (and thus capable of being manufactured without using costly machining, drilling, or casting processes). In particular, the rotation may be facilitated by coating one or both of bushing 157 and pin 120 with a hard thin film including DLC to reduce friction and potential galling between bushing 157 and pin 120. Alternatively or additionally, the rotation may be facilitated by introducing a lubricating fluid through lubrication channels 212, 312 (shown in FIGS. 2 and 3) between bushing 157 and pin 120.

Track joint assembly 100 may be configured to minimize the total amount of material required to manufacture the assembly. Such minimization may be achieved by providing a hard thin film coating including DLC over the outer diameter surface of the pins, which may eliminate the need for sleeve bearings or additional bushings, even under high load applications. The additional manufacturing step of first providing an isotropic finished outer diameter surface on the pin before applying the hard thin film coating further enhances the ability of the assembly to withstand high loads. Elimination of intermediate sleeve bearings between the pin and bushing also enhances the direct connections between links 110a, 110b as discussed above, and may strengthen and improve the durability of track joint assembly 100.

It will be apparent to those skilled in the art that various modifications and variations can be made to the disclosed track joint assemblies. Other embodiments will be apparent to those skilled in the art from consideration of the specification and practice of the disclosed track joint assemblies. It is intended that the specification and examples be considered as exemplary only, with a true scope being indicated by the following claims and their equivalents.

What is claimed is:

1. An undercarriage track joint assembly, comprising:
a first link having a first bore at a first end and a second bore at a second, opposite end;
a second link having a first bore at a first end and a second bore at a second, opposite end;
a pin extending between the first and second links and positioned at least partially within the first bores of the first and second links, or partially within the second bores of the first and second links;
a bushing extending between the first and second links, a central axial bore being defined through the bushing; and
the pin extending through the central axial bore through the bushing, the pin being coated with a diamond-like carbon (DLC) coating over at least a portion of an outer diameter surface of the pin, the coating providing a contact layer between the outer diameter surface of the pin and an inner diameter surface of the central axial bore through the bushing.

2. The undercarriage track joint assembly of claim 1, wherein the pin comprises the outer diameter surface finished by an isotropic finishing process before application of the coating.

3. The track joint assembly of claim 1, wherein the pin comprises the DLC coating being at least one of an amorphous diamond-like carbon (a-DLC) coating and a tetrahedral amorphous carbon (ta-C) coating applied over an underlayer comprising at least one element from the chromium group (group VIB).

4. The track joint assembly of claim 3, wherein the DLC coating is approximately twice the thickness of the underlayer.

5. The track joint assembly of claim 3, wherein a total thickness of the underlayer and the DLC coating on the outer diameter surface of the pin falls within the range from approximately 2-20 μm.

6. The track joint assembly of claim 1, wherein the DLC coating comprises a carbon content within the range from approximately 60-80 atomic percent (at %).

7. The track joint assembly of claim 1, wherein the DLC coating is applied using a plasma assisted chemical vapor deposition (PACVD) process.

8. The track joint assembly of claim 2, wherein an underlayer comprising at least one element from the chromium group (group VIB) is applied over the isotropic finished outer diameter surface of the pin, and the DLC coating is applied over the underlayer.

9. A track pin for use in an undercarriage track joint assembly, the track pin comprising:
an outer diameter surface prepared by a finishing operation that substantially removes surface asperities left by machining operations; and
a coating applied over the outer diameter surface, the coating comprising:
a sputtered underlayer; and
an amorphous diamond-like carbon (a-DLC) outer layer.

10. The track pin of claim 9, wherein the pin comprises the a-DLC outer layer applied over the underlayer, with the outer layer having a radial thickness that is approximately twice a radial thickness of the underlayer, and the underlayer comprises at least one transition metal.

11. The track pin of claim 9, wherein the a-DLC outer layer comprises a carbon content that falls within a range from approximately 60-80 atomic percent (at %).

12. The track pin of claim 9, wherein a total thickness of the underlayer and the a-DLC outer layer falls within a range from approximately 2-20 μm.

13. The track pin of claim 9, wherein the a-DLC outer layer has a hardness that is greater than approximately 10 gigapascals (GPa).

14. The track pin of claim 9, wherein the a-DLC outer layer is applied using a plasma assisted chemical vapor deposition (PACVD) process.

15. The track pin of claim 9, wherein the underlayer is applied over an isotropic finished outer diameter surface of the pin using a sputtering process, and the a-DLC outer layer is an amorphous hydrogenated carbon (a-C:H) layer applied from a gas phase over the underlayer.

16. A method of manufacturing a pin for use in an undercarriage track joint assembly, the method comprising:
finishing an outer diameter surface of the pin using a finishing process that substantially removes surface asperities left by machining operations;
depositing an underlayer over the outer diameter surface of the pin by sputtering with a transition metal carbide target; and
applying an outer layer of diamond-like carbon (DLC) over the underlayer.

17. The method of claim 16, wherein the underlayer is deposited to a first thickness, and the outer layer of DLC is deposited to a second thickness that is approximately two times the first thickness.

18. The method of claim 16, wherein the outer layer of DLC is deposited from a gas phase using a plasma assisted chemical vapor deposition (PACVD) process.

19. The method of claim 16, wherein the underlayer is deposited by sputtering with a transition metal carbide target including one or more elements from the chromium group (group VIB).

20. The method of claim 16, wherein the outer layer comprises a tetrahedral amorphous carbon (ta-C) layer having a hardness falling within a range from approximately 40-80 gigapascals (GPa).
